(19) United States
(12) Patent Application Publication
(10) Pub. No.: US 2026/0367127 A1
(43) Pub. Date: Nov. 19, 2026

(54) SYSTEM AND METHOD FOR CHARACTERIZING IN-BAND NONLINEAR DISTORTION USING REVERBERATION CHAMBER

(71) Applicant: KEYSIGHT TECHNOLOGIES, INC., SANTA ROSA, CA (US)

(72) Inventor: Jan Verspecht, Santa Rosa, CA (US)

(21) Appl. No.: 19/211,092

(22) Filed: May 16, 2025

(51) Int. Cl. G01R 29/10; G01R 31/28

(52) U.S. Cl. CPC G01R 29/105; G01R 31/2822

(57) ABSTRACT

A method is provided for characterizing in-band nonlinear distortion generated by a wireless device under test (DUT) having an integrated antenna using a reverberation chamber including at least one stirrer. The method includes inputting a stimulus signal to the wireless DUT located inside the reverberation chamber while the at least one stirrer is sequentially set to multiple different positions; sequentially measuring multiple output signals output by the wireless DUT in response to the stimulus signal with the at least one stirrer set to the multiple different positions, respectively, to obtain multiple measured output signals; calculating equalized channel capacity (ECC) of the wireless DUT based on the multiple measured output signals, where the ECC quantifies modulation quality of the measured output signals; and characterizing the in-band nonlinear distortion generated by the wireless DUT based on the modulation quality of the measured output signals.

### BACKGROUND

Wireless radio frequency (RF) devices, such as active phase arrays, often have integrated antennas, which can only be tested over-the-air (OTA). One such test is nonlinear distortion, which indicates distortion of an output signal waveform of the RF device relative to the input signal waveform, indicating a nonlinear relationship between the input and output signals. The amount of nonlinear distortion generated by wireless RF devices may be expressed as error vector magnitude (EVM), which is typically characterized in an anechoic chamber, such as a compact antenna test range (CATR), for example. An advantage of performing OTA testing in an anechoic chamber is that the anechoic chamber accurately characterizes directional dependency of any quantity. A disadvantage is that the anechoic chamber requires precise mechanical positioners and high-quality electro-magnetic wave absorbers. Other disadvantages of anechoic chambers are that they are relatively large, expensive, and require precise mechanical calibration.

In addition, there are instances, for example during production, when overall, non-directional quantities of the wireless RF device, such as total radiated power (TRP), for example, must be measured quickly. The use of an anechoic chamber for measuring such non-directional quantities is not efficient. It is typically more cost effective and faster to use another type of chamber, namely a reverberation (“reverb”) chamber.

A reverberation chamber is generally the opposite of an anechoic chamber. That is, rather than absorbing all reflections from the chamber walls, a reverberation chamber is constructed such that it reflects all electro-magnetic waves that are incident on the walls back into the chamber. The reverberation chamber is constructed to provide a large number of reflections, whereby both polarizations and angles of the reflections are randomized. Because all these reflections interfere with one another, the result is an electro-magnetic field inside the reverberation chamber that can be considered pseudo-random. A reverberation chamber contains one or more moveable metallic structures, called stirrers, that are adjustable to different positions. The different positions of the stirrers result in different pseudo-random electro-magnetic field distributions.

When a radiating device is placed inside a reverberation chamber, a sensing probe, typically mounted on a wall of the chamber, detects electro-magnetic power. The sensing probe detects electro-magnetic power not only from one specific direction relative to the radiating device, as is the case in an anechoic chamber, but also from all other directions of the device. By performing measurements of quantity, such as power, for a set of stirrer positions, statistical processing of the data results in a measure that is direction insensitive and that can be associated with the overall radiation pattern.

However, measuring in-band nonlinear distortion within a reverberation chamber is extremely difficult. The reason is that the reverberation chamber introduces a significant amount of linear dispersion, which makes it virtually impossible to demodulate the received signals since the equalization filter would require many more filter taps than conventional demodulation algorithms can handle. As mentioned above, in-band nonlinear distortion is typically characterized as EVM. Legacy methods for measuring EVM are all based on demodulating the signal, and they therefore cannot be used to determine EVM in a reverberation chamber, which generally is unable to demodulate signals.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a simplified block diagram of a system for characterizing in-band nonlinear distortion generated by a wireless device under test (DUT) in a reverberation chamber, according to a representative embodiment.

FIG. 2 shows an illustrative transfer function of an output signal output from the wireless DUT as a function of frequency.

FIG. 3 shows power spectral density of an input signal input to a DUT in each of a conventional anechoic chamber and a reverberation chamber according to a representative embodiment.

FIG. 4A shows simulated power spectral density of an output signal output from the DUT in a conventional anechoic chamber in response to the input signal of FIG. 3.

FIG. 4B shows simulated power spectral density of an output signal output from the DUT in a reverberation chamber in response to the input signal of FIG. 3, according to a representative embodiment.

FIG. 5 shows a simulated equalized channel capacity density (ECCD) trace of an output signal output from the DUT in each of a conventional anechoic chamber and a reverberation chamber according to a representative embodiment.

FIG. 6 shows a simulated ECCD trace of an output signal output from the DUT in a conventional anechoic chamber and a simulated maximum ECCD trace of multiple output signals output from the DUT in a reverberation chamber at different stirrer positions, respectively, according to a representative embodiment.

FIG. 7 shows a comparison of equalized channel capacity (ECC) of output signals output from the DUT in a conventional anechoic chamber and ECC of output signals output from the DUT in a reverberation chamber according to a representative embodiment.

FIG. 8 is a flow diagram of a method for characterizing in-band nonlinear distortion generated by a wireless DUT in a reverberation chamber, according to a representative embodiment.

FIG. 9 is a flow diagram of a method for calculating ECC of the wireless DUT based on the measured output signals for characterizing in-band nonlinear distortion generated by a wireless DUT in a reverberation chamber, according to a representative embodiment.

### DETAILED DESCRIPTION

In the following detailed description, for purposes of explanation and not limitation, representative embodiments disclosing specific details are set forth in order to provide a thorough understanding of an embodiment according to the present teachings. Descriptions of known systems, devices, materials, methods of operation and methods of manufacture may be omitted so as to avoid obscuring the description of the representative embodiments. Nonetheless, systems, devices, materials and methods that are within the purview of one of ordinary skill in the art are within the scope of the present teachings and may be used in accordance with the representative embodiments. It is to be understood that the terminology used herein is for purposes of describing particular embodiments only and is not intended to be limiting. The defined terms are in addition to the technical and scientific meanings of the defined terms as commonly understood and accepted in the technical field of the present teachings.

It will be understood that, although the terms first, second, third etc. may be used herein to describe various elements or components, these elements or components should not be limited by these terms. These terms are only used to distinguish one element or component from another element or component. Thus, a first element or component discussed below could be termed a second element or component without departing from the teachings of the present disclosure.

The terminology used herein is for purposes of describing particular embodiments only and is not intended to be limiting. As used in the specification and appended claims, the singular forms of terms “a,” “an” and “the” are intended to include both singular and plural forms, unless the context clearly dictates otherwise. Additionally, the terms “comprises,” and/or “comprising,” and/or similar terms when used in this specification, specify the presence of stated features, elements, and/or components, but do not preclude the presence or addition of one or more other features, elements, components, and/or groups thereof. As used herein, the term “and/or” includes any and all combinations of one or more of the associated listed items.

Unless otherwise noted, when an element or component is said to be “connected to,” “coupled to,” or “adjacent to” another element or component, it will be understood that the element or component can be directly connected or coupled to the other element or component, or intervening elements or components may be present. That is, these and similar terms encompass cases where one or more intermediate elements or components may be employed to connect two elements or components. However, when an element or component is said to be “directly connected” to another element or component, this encompasses only cases where the two elements or components are connected to each other without any intermediate or intervening elements or components.

The present disclosure, through one or more of its various aspects, embodiments and/or specific features or sub-components, is thus intended to bring out one or more of the advantages as specifically noted below. For purposes of explanation and not limitation, example embodiments disclosing specific details are set forth in order to provide a thorough understanding of an embodiment according to the present teachings. However, other embodiments consistent with the present disclosure that depart from specific details disclosed herein remain within the scope of the appended claims. Moreover, descriptions of well-known apparatuses and methods may be omitted so as not to obscure the description of the example embodiments. Such methods and apparatuses are within the scope of the present disclosure.

The various embodiments are in the technical field of measuring signals transmitted from wireless devices, and are directed to determining in-band nonlinear distortion of the wireless devices using reverberation chambers. Use of reverberation chambers reduces complexity, time and expense of determining in-band nonlinear distortion of electronic device using anechoic chambers.

In particular, there are a number of advantages of measuring in-band nonlinear distortion in reverberation chambers as compared to anechoic chambers. Measurements may be performed much faster since there is no need to scan beam patterns of the signals being measured. The equipment is much cheaper since reverberation chambers lack the expensive features of anechoic chambers, such as absorbers, positioners, and reflectors (for a CATR). The reverberation chambers are also significantly smaller than anechoic chambers, and may be used in benchtop configurations. For example, the linear dimension of a reverberation chamber as compared to an anechoic chamber may be reduced by at least a factor of five, leading to a volume that is reduced by a factor of over 100. Also, because testing in a reverberation chamber is inherently not sensitive to the direction of the DUT relative to the reverberation chamber sensing probe used for signal collection, there is no need for sensitive and time-consuming mechanical calibration processes.

According to a representative embodiment, a method is provided for characterizing in-band nonlinear distortion generated by a wireless DUT, using a reverberation chamber including at least one stirrer. The method includes inputting a stimulus signal to the wireless DUT located inside the reverberation chamber while the at least one stirrer is sequentially set to multiple different positions; sequentially measuring multiple output signals output by the wireless DUT in response to the stimulus signal with the at least one stirrer set to the multiple different positions, respectively, to obtain multiple measured output signals; calculating equalized channel capacity (ECC) of the wireless DUT based on the multiple measured output signals, where the ECC quantifies modulation quality of the measured output signals; and characterizing the in-band nonlinear distortion generated by the wireless DUT based on the modulation quality of the measured output signals.

According to another representative embodiment, a system is provided for characterizing in-band nonlinear distortion generated by a wireless DUT. The system includes a reverberation chamber comprising at least one stirrer and a sensing probe, where the wireless DUT is positioned within the reverberation chamber; means for providing a stimulus signal that is input to the wireless DUT positioned within the reverberation chamber while the at least one stirrer is sequentially set to multiple different positions, where the sensing probe receives multiple output signals output by the wireless DUT in response to the stimulus signal with the at least one stirrer set to the multiple different positions, respectively; an analog-to-digital converter (ADC) configured to digitize the multiple output signals received from the sensing probe; a processing unit configured to receive the digitized output signals from the ADC; and a memory storing instructions that, when executed by the processing unit, cause the processing unit to calculate ECC of the wireless DUT based on the digitized output signals, where the ECC quantifies modulation quality of the output signals, and characterize the in-band nonlinear distortion generated by the wireless DUT based on the modulation quality of the output signals.

According to another representative embodiment, a non-transitory computer readable medium stores instructions for characterizing in-band nonlinear distortion generated by a wireless DUT located inside a reverberation chamber including at least one stirrer. The instructions, when executed by at least one processing unit, cause the at least one processing unit to sequentially measure multiple output signals output by the wireless DUT in response to a stimulus signal input to the wireless DUT with the at least one stirrer set to different positions, respectively, to obtain multiple measured output signals; calculate ECC of the wireless DUT based on the multiple measured output signals, where the ECC quantifies modulation quality of the measured output signals; and characterize the in-band nonlinear distortion generated by the wireless DUT based on the modulation quality of the measured output signals.

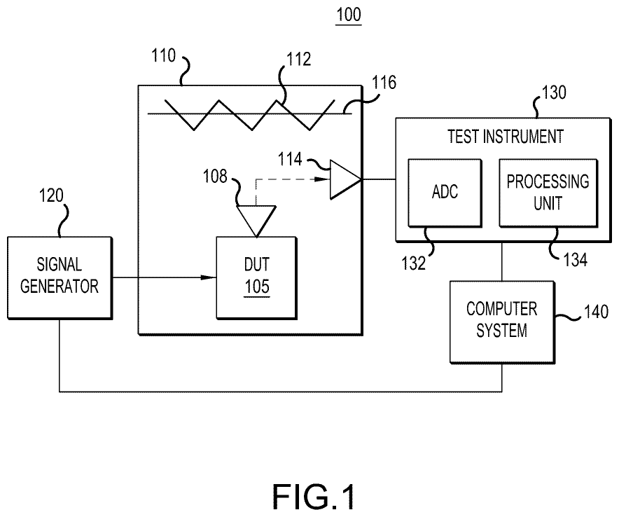

FIG. 1 is a simplified block diagram of a system for characterizing in-band nonlinear distortion generated by a wireless DUT, according to a representative embodiment. As discussed herein, in-band nonlinear distortion may be characterized indirectly using equalized channel capacity (ECC), which quantifies quality of modulation (expressed in bits/second), or may be characterized directly using error vector magnitude (EVM), which quantifies the in-band nonlinear distortion (expressed in percentage or decibels). The ECC is inversely correlated to the EVM, meaning that a high modulation quality corresponds to a low in-band nonlinear distortion and vice versa.

Referring to FIG. 1, system 100 includes a reverberation chamber 110, a signal generator 120 (optional), a test instrument 130, and a computer system 140, for testing wireless DUT 105. In the depicted embodiment, the DUT 105 includes integrated antenna 108, which is generally not accessible and cannot be tested independently of the DUT 105, thus requiring over-the-air (OTA) testing. The DUT 105 may be any device that accepts an input signal (stimulus signal), digital or analog, as input and that produces an analog output signal (response signal) in response to the input signal. As such, the DUT 105 may be an amplifier, a mixer, a frequency convertor, or a transmitter, for example, although other types of DUTs may be incorporated without departing from the scope of the present teachings.

The DUT 105 is positioned within the reverberation chamber 110 by the operator to enable measurement of its transmission characteristics, including in-band nonlinear distortion. The signal generator 120 is configured to generate the input signals that are input to the wireless DUT 105, which provides the output signals from the integrated antenna 108 in response. The signal generator 120 generates analog input signals, in particular, as discussed below. The test instrument 130 and/or the computer system 140 are configured to receive the output signals, and to measure the transmission characteristics of DUT 105, including the in-band nonlinear distortion, based on the received output signals, as discussed below.

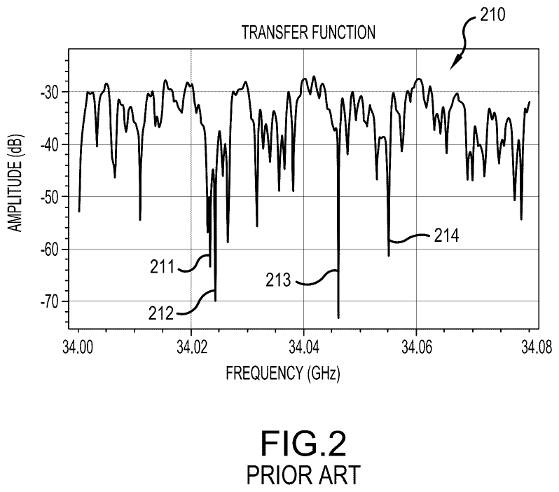

Generally, the reverberation chamber 110 is a screened room or container lined with low absorption materials to provide minimum absorption (and maximum reflection) of electromagnetic energy output by the DUT 105. For example, the reverberation chamber 110 may be lined with galvanized steel, aluminum, or copper to internally reflect the output signals transmitted from the DUT 105 via the integrated antenna 108 in response to the stimulus signals. As a result, the transfer function of the reverberation chamber 110 becomes a pseudo-random distribution, and includes values that are more than 30 dB below the maximum value at certain frequencies. The frequencies at which these low values of the transfer function occur may be referred to as “nulls,” discussed below. FIG. 2 shows an illustrative transfer function of an output signal output from the DUT 105 as a function of frequency. Referring to FIG. 2, transfer function 210 includes a number of nulls, indicated by representative nulls 211, 212, 213 and 214, which have amplitudes less than −60 dB, for example.

The reverberation chamber 110 includes one or more sensing probes, indicated by representative sensing probe 112, configured to receive the output signals transmitted by the DUT 105, which may be RF signals, along with reflected portions of the output signals reflected by the walls of the reverberation chamber 110. The sensing probe 112 may be a probe antenna, an array antenna, or a horn antenna, for example. The reverberation chamber 110 further includes one or more stirrers (tuners), indicated by representative stirrer 114. The stirrer 114 may include one or more metallic reflectors that are movable to different orientations in response to different positions of the stirrer 114. The different positions of the stirrer 114 change reflection characteristics of the reverberation chamber 110. For example, the stirrer 114 may be rotated about an axis 116 to place the metallic reflectors at the different orientations corresponding to the different positions of the stirrer 114. The measurements are made of the output signals at the positions of the stirrer 114 while the positions temporarily remain fixed, respectively, as discussed below.

The output signals received by the sensing probe 112 are input to the test instrument 130 for performing measurements. The test instrument 130 may be any compatible test instrument capable of processing the output signals and enabling measurements of at least modulation quality and in-band nonlinear distortion as discussed herein, such as a spectrum analyzer, a vector signal analyzer, a vector network analyzer, or a digital oscilloscope, for example. The test instrument 130 may be a receiver, such as an equalizing receiver, for example, which is an RF receiver that extracts information solely based on linear operators, such as equalization, sampling, and Fourier transform. Examples of equalizing receivers include receivers used with orthogonal frequency domain multiplexing (OFDM), code division multiple access (CDMA), and single carrier modulation schemes such as quadrature phase shift keying (QPSK) and quadrature amplitude modulation (QAM), for example.

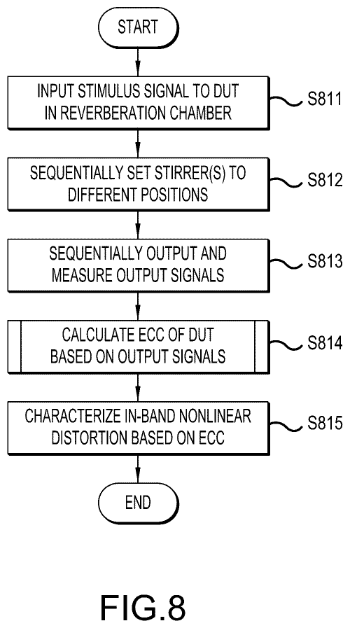

The test instrument 130 includes an analog-to-digital converter (ADC) 132 configured to digitize the output signals to provide digitized output signals. Although not shown, the test instrument 130 may also include a heterodyning receiver that includes one or more additional front-end signal processing components, such as filters for performing high-pass, low-pass and/or band-pass filtering, and a local oscillator and a mixer for performing frequency down-conversion and/or frequency up-conversion of the output signal, depending on the test requirements, as would be apparent to one skilled in the art. The test instrument 130 may further include a processing unit 134, such as a digital signal processor (DSP), for example, for processing the digitized output signals. An example of the processing unit 134 is provided by illustrative processing unit 800 shown in FIG. 8, discussed below.

The computer system 140 is coupled to each of the reverberation chamber 110, the signal generator 120, and the test instrument 130 in order to control the measurement procedure described herein. That is, the computer system 140 is configured to control the signal generator 120 to generate and transmit analog input signals (stimulus signals) to the DUT 105, which provides output signals (response signals) in response, which are received by the sensing probe 112. The computer system 140 may provide digital input signals directly to the DUT 105, by-passing the signal generator 120, as discussed below. The computer system 140 is further configured to sequentially change the position of the stirrer 114 in the reverberation chamber 110 while the DUT 105 receives the input signal. To do so, the computer system 140 may interface with a servo motor (not shown), for example, coupled to the stirrer 114 in order to rotate the stirrer 114 on its axis 116, as would be apparent to one skilled in the art. Alternatively, the stirrer 114 may be positioned or rotated manually by the operator.

The computer system 140 is also configured to receive signal measurements from the test instrument 130, and to calculate the ECC of the DUT 105 based on the measured output signals, and to determine the in-band nonlinear distortion generated by the DUT 105 based on the ECC, as discussed below. ECC is the maximum data transmission rate possible when using an ideal equalizing receiver, which indicates modulation quality. EVM may be determined from the ECC, where EVM is a direct measure of in-band nonlinear distortion, as discussed below.

Alternatively, the test instrument 130 may be configured to calculate one or both of the ECC and the EVM of the DUT 105 without departing from the scope of the present teachings. The computer system 140 includes at least a processing unit, as discussed below with reference to illustrative processing unit 1000 shown in FIG. 10.

In an embodiment, an input signal is input to the DUT 105, positioned within the reverberation chamber 110, while the stirrer 114 is sequentially set to multiple different positions, e.g., manually or under control of the computer system 140. The different positions of the stirrer 114 may be set arbitrarily, for example. The sensing probe 112 receives output signals from the DUT 105 via the antenna 108 in response to the input signal with the stirrer 114 set to the different positions, respectively.

In an embodiment, the input signal is a pseudo-random periodically modulated RF carrier signal. The pseudo-random periodically modulated RF carrier signal may be designed such that it matches statistics of the expected operating condition of the DUT 105, such as power, signal bandwidth, and complementary cumulative distribution function (CCDF) of the amplitude, for example. The pseudo-random periodically modulated RF carrier signal may be a “flat tones” signal, which is a multitone signal that has a uniform spacing between adjacent tones. All of the tones have the same amplitude and a pseudo-random phase. Accordingly, the flat tones signal mimics statistics of any multi-carrier signal, such as an OFDM modulation formatted signal, for example. Notably, the uniform spacing between the adjacent tones in the pseudo-random periodically modulated input signal is significantly (at least three times) less than the reciprocal of a duration of an impulse response of the reverberation chamber 110 to avoid underestimation of the ECC.

The input signal input to the DUT 105 within the reverberation chamber 110 may be an analog signal in nature when the DUT 105 has an analog input, or a digital signal in nature when the DUT 105 has a digital input. When the input signal is to be an analog signal, the signal generator 120 may be a vector signal generator configured to output a modulated input signal, or an arbitrary waveform generator (AWG) configured to generate a set of baseband signals that frequency upconverted by the DUT 105, for example. When the input signal is to be a digital signal, the signal generator 120 is bypassed and the computer system 140 directly provides the digital input signal to the DUT 105 by a wireless or wired connection.

The input signal is provided to the DUT 105 while the stirrer 114 of the reverberation chamber 110 is sequentially set to multiple different positions. For example, the input signal may be input to the DUT 105 continuously while the stirrer 114 is sequentially set to different rotational positions, e.g., under control of the computer system 140. In an embodiment, the different positions to which the stirrer 114 is set may be selected arbitrarily. The stirrer 114 remains fixed in each of the different positions while measurement data is collected, e.g., by the test instrument 130, from the output signal of the DUT 105 in response to the input signal. Upon completion of the measurement of the output signal of the DUT 105, the stirrer 114 is set to the next position. The time for performing the measurement may range from 100 ms to 60 seconds, for example, as determined by the test instrument 130 performing the measurement. The output signals output by the DUT 105 and received by the sensing probe 112 differ from one another due to different transfer functions being applied to the output signals from the different signal reflections and interferences caused by the different positions of the stirrer 114, respectively.

The ECC, which quantifies the quality of the modulation, is inversely correlated with the nonlinear in-band distortion, and is calculated by performing cross-spectral data analysis on the known input signal and the measured responsive output signals from the DUT 105, as explained by J. Verspecht, “Quantifying Modulation Quality at the Physical Layer using Equalized Channel Capacity,” Proceedings of the 51^{st} European Microwave Conference (Apr. 6, 2022), the contents of which are incorporated herein by reference in their entirety. Unlike conventional systems that rely on EVM for determining nonlinear in-band distortion, the embodiments herein calculate an equalized channel capacity density (ECCD) value as a function of frequency, which has a unit of bits. The ECCD value is generally an accurate representation of the quality of the modulation of the DUT 105, except for the nulls where the transfer function of the reverberation chamber 110 between the DUT 105 and the sensing probe 112 has low values (e.g., zero or close to zero), as shown in FIG. 5, for example, discussed below.

The locations of the nulls depend on the respective positions of the stirrer 114 in the reverberation chamber 110. Therefore, in order to avoid negative effects of the nulls, ECCD values are determined at the frequencies across the signal bandwidth of the output signals output by the DUT 105 for each of the different positions of the stirrer 114. In other words, at each position of the stirrer 114, a set of ECCD values is determined for a corresponding set frequencies of the signal bandwidth. Then, the maximum ECCD value among the ECCD values determined at each frequency is selected. The ECC of the DUT 105 is determined by integrating the maximum ECCD values over the signal bandwidth. In practice, as few as three positions of the stirrer 114 result in an accurate determination of the ECCD values of the DUT 105. In various embodiments, the number of different stirrer positions required for determining a sufficient number of corresponding ECCD values to quantify the quality of the modulation may be predetermined by the user or may be determined via feedback during the measurement process. For example, the ECC of the DUT 105 may be calculated from each ECCD value in response to a current stirrer position, and compared to the ECC of the previous stirrer position. No more measurements will be made using additional stirrer positions once the ECC of the current stirrer position changes by less than a predetermined relative tolerance (e.g., one percent from the ECC) of the previous stirrer position. The ECC may be used to quantify the quality of the modulation of the DUT 105 directly. Or, the ECC may be converted to EVM using known conversion techniques, and the EVM may then be used to quantify the in-band nonlinear distortion of the DUT 105 directly.

The ECCD value is determined according to Equation (1):

$$ECCD = {c}_{D E} ( f ) = - {log}_{2} ( 1 - \frac{{S}_{XY} ( f ) {S}_{YX} ( f )}{{S}_{XX} ( f ) {S}_{YY} ( f )} ) \qquad ( 1 )$$

The ECC is value is determined by integrating ECCD values over signal bandwidth of the output signal, according to Equation (2):

$$ECC = {C}_{E} ( F ) = - {\int }_{F} {log}_{2} ( 1 - \frac{{S}_{XY} ( f ) {S}_{YX} ( f )}{{S}_{XX} ( f ) {S}_{YY} ( f )} ) df \qquad ( 2 )$$

The following Equations (3)-(6) apply to Equations (1) and (2), where X(f) is the spectral representation of the input signal x(t) (stimulus signal), Y(f) is the spectral representation of the output signal y(t) (response signal), * denotes conjugate, and E[.] represents the statistical expectation operator:

S_{XX}(f)=E[x*(f)x(f)] (3)

S_{YY}(f)=E[Y*(f)Y(f)] (4)

S_{YX}(f)=E[Y*(f)X(f)] (5)

S_{XY}(f)=E[X*(f)Y(f)] (6)

Again, the maximum ECCD value is selected for each frequency within the signal bandwidth of the output signals output by the DUT 105 with the stirrer 114 in different positions, respectively. The ECC is determined by Equation (2) as the integration of the these maximum ECCD values.

In an embodiment, measuring ECCD (c_{DE}(f)) begins by applying a finite length or repetitive input signal (stimulus signal) x₁(t) to the DUT 105, where x₁(t) is statistically representative of the modulation format for which the measurements are to be performed. The corresponding output signal (response signal) y₁(t) is then measured with the stirrer 114 in different positions, as discussed above. A spectral estimation technique is employed to provide measurements of the quantities Sₓₓ(f), S_{yy}(f), S_{yx}(f) and S_{xy}(f), as would be apparent to one skilled in the art. An example of such spectral estimation techniques is provided by D. Thomson, “Spectral Estimation and Harmonic Analysis,” Proceedings of the IEEE, Vol. 70, No. 9 (September 1982), the contents of which are incorporated herein by reference in their entirety. The ECCD (c_{DE}(f)) may then be derived according to Equations (1) and (2), respectively, using the measured quantities Sₓₓ(f), S_{yy}(f), S_{yx}(f) and S_{xy}(f).

The quality of the modulation may be directly quantified by the ECC. Alternatively, or in addition, the ECC may be converted into EVM or other figures-of-merit for quantifying nonlinear distortion from the quality of modulation, such as noise-power-ratio (NPR). For example, the ECC may be converted to EVM in decibels and NPR in decibels according to Equation (7):

EVM=NPR=−10 log₁₀(2)ECC≈−3.01ECC (7)

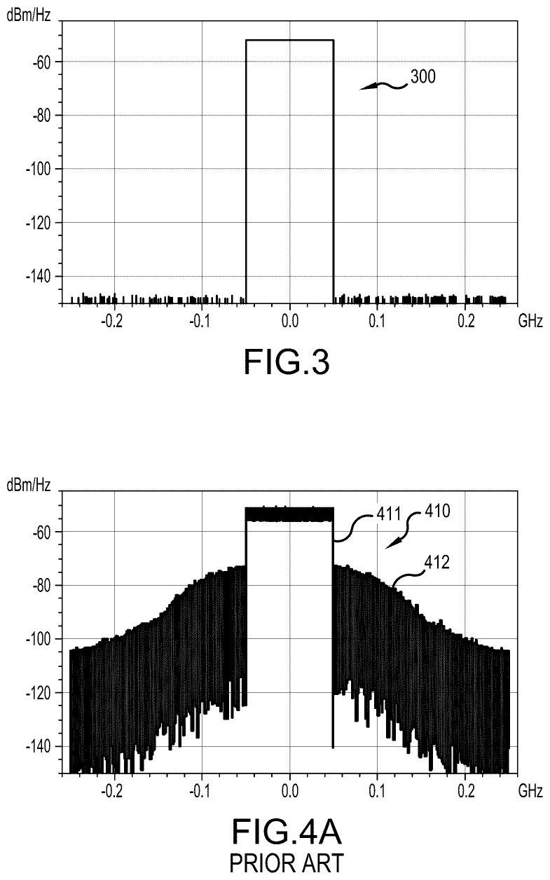

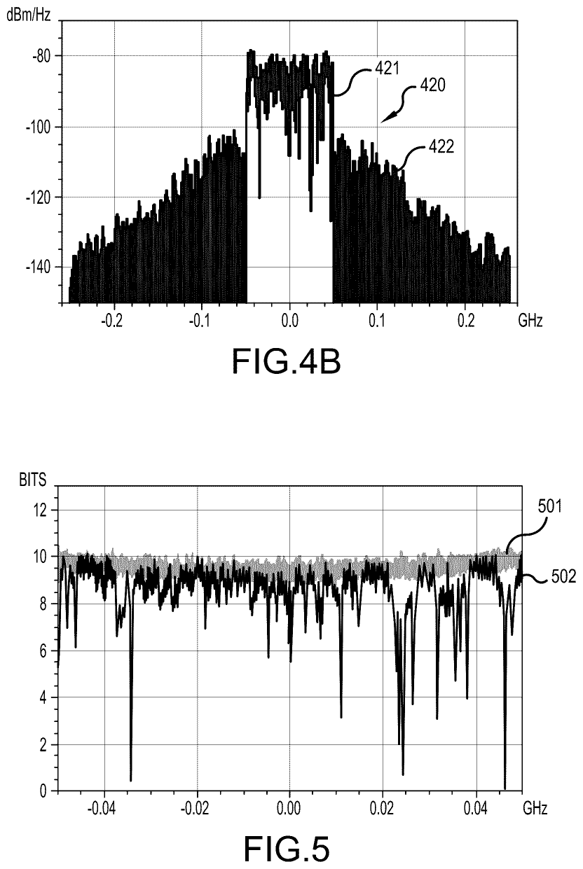

FIG. 3 shows power spectral density of an input signal input to a DUT in each of a conventional anechoic chamber (FIG. 4A) and a reverberation chamber (FIG. 4B) according to a representative embodiment. Referring to FIG. 3, input signal 300 is a pseudo-random periodically modulated stimulus signal provided to the DUT. The x-axis shows frequency of the input signal 300 in GHz relative to the RF carrier, and the y-axis shows the power spectral density of the input signal 300 in dBm/Hz.

FIG. 4A shows simulated power spectral density of an output signal output from the DUT in the conventional anechoic chamber in response to the input signal of FIG. 3. Referring to FIG. 4A, output signal 410 is output from the DUT in response to the input signal 300, as would be measured in a conventional anechoic chamber. The output signal 410 includes nonlinear in-band distortion 411 and out-of-band distortion 412 (spectral regrowth). The x-axis shows frequency of the output signal 410 in GHz relative to the RF carrier, and the y-axis shows the power spectral density of the output signal 410 in dBm/Hz.

FIG. 4B shows simulated power spectral density of an output signal output from the DUT in the reverberation chamber (e.g., reverberation chamber 110) in response to the input signal of FIG. 3, according to a representative embodiment. Referring to FIG. 4B, output signal 420 is output from the DUT in response to the input signal 300, as would be measured in a reverberation chamber for a fixed stirrer position. The output signal 420 includes nonlinear in-band distortion 421 and out-of-band distortion 422 (spectral regrowth). The x-axis shows frequency of the output signal 420 in GHz relative to the RF carrier, and the y-axis shows the power spectral density of the output signal 420 in dBm/Hz.

As shown in FIG. 4B, the in-band power of the output signal 420 fluctuates drastically across the signal bandwidth, as indicated by the nonlinear in-band distortion 421, as compared to the output signal 410 in FIG. 4A. This is because the transfer function of the reverberation chamber changes rapidly as a function of frequency. The nonlinear in-band distortion 421 may be calculated by performing cross-spectral data analysis on the known input signal 300 and the measured response of the output signal 420, as discussed above with reference to Equations (1) and (2). That is, ECCD values are calculated as a function of frequency across the signal bandwidth of the output signals, such that each measured output signal (including output signal 420) has corresponding ECCD values at the frequencies of the signal bandwidth, respectively.

FIG. 5 shows a simulated ECCD trace of an output signal output from the DUT in each of a conventional anechoic chamber and a reverberation chamber according to a representative embodiment. Referring to FIG. 5, ECCD trace 501 indicates ECCD values as measured in the anechoic chamber, providing reference ECCD values. ECCD trace 502 indicates ECCD values as measured in the reverberation chamber at one position of the stirrer, such that nulls exist at certain frequencies of the output signal. At those frequencies, the ECCD values are inaccurate due to a lack of dynamic range, and the resulting calculated ECCD values will have a significant negative bias near the nulls. The x-axis shows frequency of the output signals in GHz relative to the RF carrier, and the y-axis shows the ECCD of the output signals in numbers of bits.

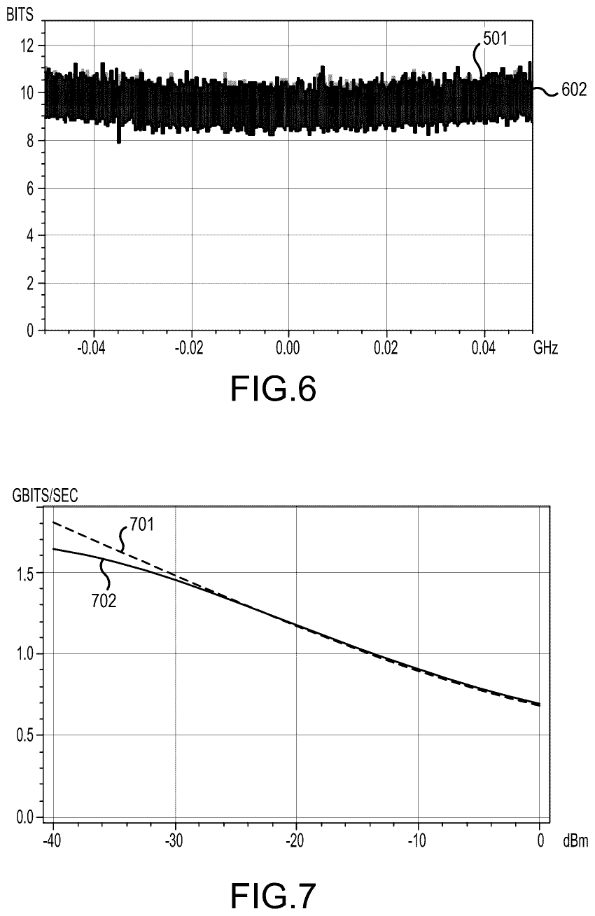

FIG. 6 shows a simulated ECCD trace of an output signal output from the DUT in a conventional anechoic chamber and a simulated maximum ECCD trace from multiple output signals output from the DUT in a reverberation chamber at different stirrer positions, respectively, according to a representative embodiment. Referring to FIG. 6, the ECCD trace 501 indicates the ECCD values as measured in the anechoic chamber, as discussed above with reference to FIG. 5. ECCD trace 602 indicates maximum ECCD values taken from ECCD values measured in the reverberation chamber at different positions of the stirrer, respectively. By selecting the maximum values, the nulls that existed at certain frequencies of the one output signal have been eliminated. The maximum ECCD trace 602 is therefore nearly identical to the ECCD trace 501 of the output signal from the DUT in the anechoic chamber, which is known to provide accurate in-band nonlinear distortion measurements. Integration across the signal bandwidth of the final maximum ECCD versus frequency results in the overall ECC, as discussed above. The x-axis shows frequency of the output signals in GHz relative to the RF carrier, and the y-axis shows the ECCD of the output signals in numbers of bits.

FIG. 7 shows a comparison of ECC of output signals output from the DUT in a conventional anechoic chamber and ECC of output signals output from the DUT in a reverberation chamber, according to a representative embodiment. Referring to FIG. 7, trace 701 shows ECC of the output signal from the DUT in the anechoic chamber in Gbits/second as a function of input power, and trace 702 shows ECC of the output signal from the DUT in the reverberation chamber in numbers of Gbits/second as a function of input power. Traces 701 and 702 indicate good correspondence between the two methods, except when the level exceeds 1.4 Gbits/second. For practical purposes, though, it is largely sufficient to characterize up to a level of 13 bits times the signal bandwidth, which in this case corresponds to 1.3 Gbits/second. If necessary, accuracy for a larger number of bits/second can be reached by using more tones in the input signal, which leads to a better estimation of the underlying transfer function of the reverberation chamber.

FIG. 8 is a flow diagram illustrating a method of characterizing in-band nonlinear distortion generated by a wireless DUT using a reverberation chamber including at least one stirrer, according to a representative embodiment. The steps of FIG. 8 may be implemented by one or both of the processing unit 134 and the computer system 140 depicted in FIG. 1, for example, where instructions for performing the various steps are stored on a non-transitory computer readable medium, such as memory 1020 depicted in FIG. 10, for example.

Referring to FIG. 8, an input signal (stimulus signal) is input to the wireless DUT in block S811, where the DUT is located inside the reverberation chamber. The input signal is a pseudo-random periodically modulated stimulus signal that matches statistics of an expected operating condition of the wireless DUT.

In block S812, the at least one stirrer of the reverberation chamber is sequentially set to multiple different positions as the input signal continues to be input to the wireless DUT. It was heuristically determined that three different stirrer positions are usually sufficient, although more accurate results may be achieved by using more stirrer positions. In one implementation, the number of stirrer positions is increased until the resulting ECC value is within a certain predetermined relative tolerance compared to the previous ECC value. A typical relative tolerance could be one percent, for example.

In block S813, multiple output signals (response signals) are sequentially output by the wireless DUT in response to the input signal with the at least one stirrer set to the multiple different positions, respectively. The output signals, which may be RF signals, are received by a sensing probe in the reverberation chamber, and sequentially measured to obtain multiple measured output signals. The at least one stirrer remains in each of the different positions for an amount of time sufficient to measure output signals from the DUT with the at least one stirrer in that position.

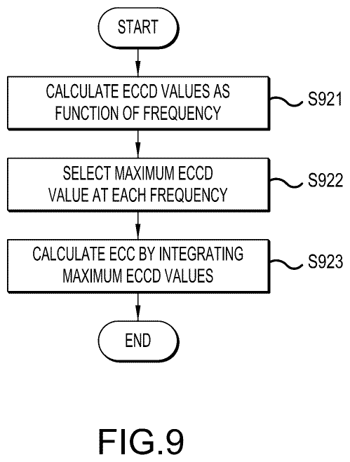

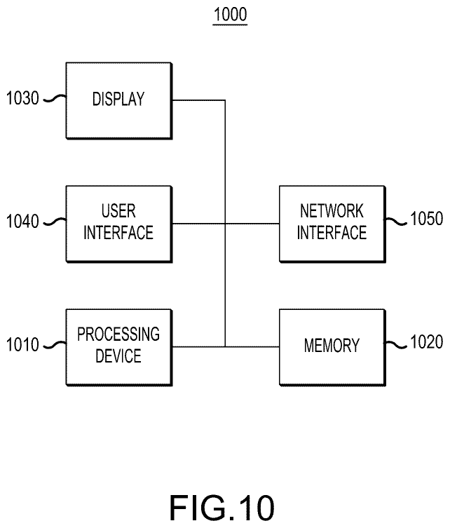

Block S814 indicates a process of calculating equalized channel capacity (ECC) of the wireless DUT based on the measured output signals. FIG. 9 is a flow diagram of the process for calculating ECC of the wireless DUT based on the measured output signals for determining in-band nonlinear distortion generated by a wireless DUT in a reverberation chamber, according to a representative embodiment.

Referring to FIG. 9, in block S921, multiple ECCD values are calculated as a function of frequency across a signal bandwidth of the measured output signals. Accordingly, each measured output signal has corresponding ECCD values at the frequencies of the signal bandwidth, respectively.

In block S922, a maximum ECCD value is selected at each frequency of the frequencies of the signal bandwidth of the multiple measured output signals. This provides maximum ECCD values corresponding to the frequencies of the signal bandwidth, respectively.

In block S923, the ECC of the wireless DUT is calculated by integrating the maximum ECCD values over the signal bandwidth. As discussed above, the ECC quantifies the quality of modulation of the measured output signals, which is inversely correlated to the in-band nonlinear distortion.

Referring again to FIG. 8, in block S815, the in-band nonlinear distortion generated by the wireless DUT is characterized based on the ECC calculated in block S814. The in-band nonlinear distortion generated by the wireless DUT may be characterized indirectly from quality of modulation quantified by the ECC. Alternatively, or in addition, the in-band nonlinear distortion generated by the wireless DUT may be characterized directly by converting the ECC into EVM of the wireless DUT, and quantifying the in-band nonlinear distortion using the EVM, as discussed above.

As mentioned above, the test instrument 130 and the computer system 140 include processing units. FIG. 10 is a simplified block diagram showing an example of such processing unit, according to a representative embodiment.

Referring to FIG. 10, processing unit 1000 includes a processing device 1010 and memory 1020 for storing instructions executable by the processing device 1010 to implement the processes described herein, as well as a display 1030, a user interface 1040, and a network interface 1050. The processing device 1010 is representative of one or more processing devices and is configured to execute software instructions to perform functions as described in the various embodiments herein, including various steps in the methods set for in FIGS. 8 and 9, for example. The processing device 1010 may be implemented by a general purpose computer, a personal computer (PC), a central processing unit (CPU), a DSP, a graphics processing unit (GPU), one or more processors, microprocessors or microcontrollers, a state machine, a programmable logic device, field programmable gate arrays (FPGAs), application specific integrated circuits (ASICs), or combinations thereof, using any combination of hardware, software, firmware, hard-wired logic circuits, or combinations thereof.

The term “processor” encompasses an electronic component able to execute a program or machine executable instructions. References to a processor should be interpreted to include more than one processor or processing core, as in a multi-core processor, and/or parallel processors. A processor may also refer to a collection of processors within a single computer system or distributed among multiple computer systems, such as in a cloud-based or other multi-site application. Programs have software instructions performed by one or multiple processors that may be within the same computing device or which may be distributed across multiple computing devices.

The memory 1020 may include a main memory and/or a static memory, where such memories may communicate with each other and the processing device 1010 via one or more buses. The memory 1020 stores instructions used to implement some, or all aspects of methods and processes described herein, including the methods described above with reference to FIGS. 8 and 9, for example. The memory 1020 may be implemented by any number, type and combination of random-access memory (RAM) and read-only memory (ROM), for example, and may store various types of information, such as software algorithms and computer programs, all of which are executable by the processing device 1010. The various types of ROM and RAM may include any number, type and combination of computer readable storage media, such as a disk drive, flash memory, an electrically programmable read-only memory (EPROM), an electrically erasable and programmable read only memory (EEPROM), registers, a hard disk, a removable disk, tape, compact disk read only memory (CD-ROM), digital versatile disk (DVD), floppy disk, blu-ray disk, a universal serial bus (USB) drive, or any other form of storage medium known in the art.

“Memory” is an example of computer-readable storage media, and should be interpreted as possibly being multiple memories or databases. The memory or database may for instance be multiple memories or databases local to the computer, and/or distributed amongst multiple computer systems or computing devices. The memory 1020 is a tangible storage medium for storing data and executable software instructions and is non-transitory during the time software instructions are stored therein. As used herein, the term “non-transitory” is to be interpreted not as an eternal characteristic of a state, but as a characteristic of a state that will last for a period. The term “non-transitory” specifically disavows fleeting characteristics such as characteristics of a carrier wave or signal or other forms that exist only transitorily in any place at any time. The memory 1020 may store software instructions and/or computer readable code that enables performance of various functions. The memory 1020 may be secure and/or encrypted, or unsecure and/or unencrypted.

The display 1030 may be a monitor such as a computer monitor, a television, a liquid crystal display (LCD), an organic light emitting diode (OLED), a flat panel display, a solid-state display, or a cathode ray tube (CRT) display, or an electronic whiteboard, for example. The display 1030 may also provide a graphical user interface (GUI) for displaying and receiving information to and from the user.

The user interface 1040 includes a known interface for providing information and data output by the processing device 1010 and/or the memory 1020 to the user, and for receiving information and data input by the user. For example, the user interface 1040 enables the user to enter data and to control or manipulate aspects of the processes described herein, and enables the processing device 1010 to indicate the effects of the user's control or manipulation. The user interface 1040 may connect one or more user devices, such as a mouse, a keyboard, a trackball, a joystick, a haptic device, a microphone, a video camera, a touchpad, a touchscreen, voice or gesture recognition captured by a microphone or video camera, for example, or any other peripheral or control to permit user feedback from and interaction with the computer system 150.

The network interface 1050 includes a known input/output connection to a data communication network, such as a local area network (LAN), a wireless LAN, Wifi, ethernet, or the like. The network interface 1050 enables connections between the computer system 150, for example, and each of the reverberation chamber 110 and the test instrument 130, for example. The network interface 1050 may further include one or more of ports, disk drives, wireless antennas, or other types of receiver circuitry.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those having ordinary skill in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to an advantage.

Aspects of the present invention may be embodied as an apparatus, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer executable code embodied thereon.

While representative embodiments are disclosed herein, one of ordinary skill in the art appreciates that many variations that are in accordance with the present teachings are possible and remain within the scope of the appended claim set. The invention therefore is not to be restricted except within the scope of the appended claims.

1. A method of characterizing in-band nonlinear distortion generated by a wireless device under test (DUT) using a reverberation chamber including at least one stirrer, the method comprising:
inputting a stimulus signal to the wireless DUT located inside the reverberation chamber while the at least one stirrer is sequentially set to a plurality of different positions;
sequentially measuring a plurality of output signals output by the wireless DUT in response to the stimulus signal with the at least one stirrer set to the plurality of different positions, respectively, to obtain a plurality of measured output signals; and
calculating equalized channel capacity (ECC) of the wireless DUT based on the plurality of measured output signals, wherein the ECC quantifies modulation quality of the plurality of measured output signals.

2. The method of claim 1, wherein calculating the ECC of the wireless DUT comprises:
calculating a plurality of equalized channel capacity density (ECCD) values as a function of frequency across a signal bandwidth of the plurality of measured output signals, such that each measured output signal has corresponding ECCD values at the frequencies of the signal bandwidth, respectively;
selecting a maximum ECCD value at each of the frequencies of the signal bandwidth of the plurality of measured output signals to provide a plurality of maximum ECCD values corresponding to the frequencies of the signal bandwidth, respectively; and
calculating the ECC of the wireless DUT by integrating the plurality of maximum ECCD values over the signal bandwidth.

3. The method of claim 1, further comprising:
characterizing the in-band nonlinear distortion generated by the wireless DUT based on the modulation quality.

4. The method of claim 3, wherein characterizing the in-band nonlinear distortion generated by the wireless DUT based on the ECC comprises:
converting the ECC into error-vector magnitude (EVM) of the wireless DUT; and
quantifying the in-band nonlinear distortion generated by the wireless DUT using the EVM.

5. The method of claim 1, wherein the stimulus signal comprises a pseudo-random periodically modulated stimulus signal, wherein the pseudo-random periodically modulated stimulus signal matches statistics of an expected operating condition of the wireless DUT.

6. The method of claim 5, wherein the pseudo-random periodically modulated stimulus signal is a multitone signal comprising a plurality of tones with a uniform spacing between adjacent tones of the plurality of tones, and wherein each tone of the plurality of tones has a constant amplitude and a pseudo-random phase.

7. The method of claim 6, wherein the uniform spacing between the adjacent tones of the plurality of tones in the pseudo-random periodically modulated stimulus signal is significantly less than a reciprocal of a duration of an impulse response of the reverberation chamber.

8. A system for characterizing in-band nonlinear distortion generated by a wireless device under test (DUT), the system comprising:
a reverberation chamber comprising at least one stirrer and a sensing probe, wherein the wireless DUT is positioned within the reverberation chamber;
means for providing a stimulus signal that is input to the wireless DUT positioned within the reverberation chamber while the at least one stirrer is sequentially set to a plurality of different positions, wherein the sensing probe receives a plurality of output signals output by the wireless DUT in response to the stimulus signal with the at least one stirrer set to the plurality of different positions, respectively;
an analog-to-digital converter (ADC) configured to digitize the plurality of output signals received from the sensing probe to provide a plurality of digitized output signals;
a processing unit configured to receive the plurality of digitized output signals from the ADC; and
a non-transitory memory storing instructions that, when executed by the processing unit, cause the processing unit to:
calculate equalized channel capacity (ECC) of the wireless DUT based on the plurality of digitized output signals, wherein the ECC quantifies modulation quality of the plurality of output signals; and
characterize the in-band nonlinear distortion generated by the wireless DUT based on the modulation quality of the plurality of output signals.

9. The system of claim 8, wherein the processing unit calculates the ECC of the wireless DUT by:
calculating a plurality of equalized channel capacity density (ECCD) values as a function of frequency across a signal bandwidth of the plurality of output signals, such that each digitized output signal has corresponding ECCD values at the frequencies of the signal bandwidth, respectively;
selecting a maximum ECCD value at each of the frequencies of the signal bandwidth of the plurality of output signals to provide a plurality of maximum ECCD values corresponding to the frequencies of the signal bandwidth, respectively; and
calculating the ECC of the wireless DUT by integrating the plurality of maximum ECCD values over the signal bandwidth.

10. The system of claim 8, wherein the processing unit characterizes the in-band nonlinear distortion generated by the wireless DUT based on the ECC by:
converting the ECC into error-vector magnitude (EVM) of the wireless DUT; and
quantifying the in-band nonlinear distortion generated by the wireless DUT using the EVM.

11. The system of claim 8, wherein the stimulus signal comprises a pseudo-random periodically modulated stimulus signal, wherein the pseudo-random periodically modulated stimulus signal matches statistics of an expected operating condition of the wireless DUT.

12. The system of claim 11, wherein the statistics of the expected operating condition of the wireless DUT comprise power, signal bandwidth, and complementary cumulative distribution function (CCDF) of amplitude.

13. The system of claim 11, wherein the pseudo-random periodically modulated stimulus signal is a multitone signal comprising a plurality of tones with a uniform spacing between adjacent tones of the plurality of tones, and wherein each tone of the plurality of tones has a constant amplitude and a pseudo-random phase.

14. The system of claim 13, wherein the uniform spacing between the adjacent tones of the plurality of tones in the pseudo-random periodically modulated stimulus signal is significantly less than a reciprocal of a duration of an impulse response of the reverberation chamber.

15. The system of claim 11, wherein the means for providing the stimulus signal comprises a vector signal generator configured to generate an analog modulated radio frequency (RF) signal as the pseudo-random periodically modulated stimulus signal, or an arbitrary waveform generator configured to generate a set of analog baseband signals as the pseudo-random periodically modulated stimulus signal, wherein the set of analog baseband signals are frequency upconverted by the wireless DUT.

16. The system of claim 11, wherein the means for providing the stimulus signal comprises the processing unit, wherein the instructions further cause the processing unit to generate a digital input signal as the pseudo-random periodically modulated stimulus signal.

17. A non-transitory computer readable medium storing instructions for characterizing in-band nonlinear distortion generated by a wireless device under test (DUT) located inside a reverberation chamber including at least one stirrer, wherein the instructions, when executed by at least one processing unit, cause the at least one processing unit to:
sequentially measure a plurality of output signals output by the wireless DUT in response to a stimulus signal input to the wireless DUT with the at least one stirrer set to a plurality of different positions, respectively, to obtain a plurality of measured output signals;
calculate equalized channel capacity (ECC) of the wireless DUT based on the plurality of measured output signals, wherein the ECC quantifies modulation quality of the plurality of measured output signals; and
characterize the in-band nonlinear distortion generated by the wireless DUT based on the modulation quality of the plurality of measured output signals.

18. The non-transitory computer readable medium of claim 17, wherein the instructions cause the at least one processing unit to calculate the ECC of the wireless DUT by:
calculating a plurality of equalized channel capacity density (ECCD) values as a function of frequency across a signal bandwidth of the plurality of measured output signals, such that each measured output signal has corresponding ECCD values at the frequencies of the signal bandwidth, respectively;
selecting a maximum ECCD value at each of the frequencies of the signal bandwidth of the plurality of measured output signals to provide a plurality of maximum ECCD values corresponding to the frequencies of the signal bandwidth, respectively; and
calculating the ECC of the wireless DUT by integrating the plurality of maximum ECCD values over the signal bandwidth.

19. The non-transitory computer readable medium of claim 17, wherein the instructions cause the at least one processing unit to characterize the in-band nonlinear distortion generated by the wireless DUT by:
converting the ECC into error-vector magnitude (EVM) of the wireless DUT; and
quantifying the in-band nonlinear distortion generated by the wireless DUT using the EVM.

20. The non-transitory computer readable medium of claim 17, wherein the stimulus signal comprises a pseudo-random periodically modulated stimulus signal.
